(19) United States
(12) Patent Application Publication
(10) Pub. No.: US 2023/0416422 A1
(43) Pub. Date: Dec. 28, 2023

(54) COMPOSITION, METHOD FOR MANUFACTURING SEMICONDUCTOR SUBSTRATE, POLYMER, AND METHOD FOR MANUFACTURING POLYMER

(71) Applicant: JSR CORPORATION, Tokyo (JP)

(72) Inventors: Hiroki NAKATSU, Tokyo (JP); Shuhei Yamada, Tokyo (JP); Shinya Abe, Tokyo (JP); Takashi Tsuji, Tokyo (JP); Kanako Ueda, Tokyo (JP); Hiroyuki Miyauchi, Tokyo (JP)

(73) Assignee: JSR CORPORATION, Tokyo (JP)

(21) Appl. No.: 18/244,460

(22) Filed: Sep. 11, 2023

Related U.S. Application Data
(63) Continuation-in-part of application No. PCT/JP2022/009373, filed on Mar. 4, 2022.

(30) Foreign Application Priority Data
Mar. 12, 2021 (JP) 2021-040477

(51) Int. Cl. C08F 28/06; C08F 24/00

(52) U.S. Cl. CPC C08F 28/06; C08F 24/00

(57) ABSTRACT

A composition includes: a polymer including a repeating unit represented by formula (1); and a solvent. In the formula (1), Ar¹ is a divalent group including an aromatic ring having 10 to 40 ring atoms; and R⁰ is a monovalent group including a heteroaromatic ring which includes a sulfur atom as a ring-forming atom.

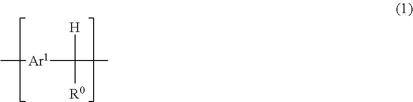

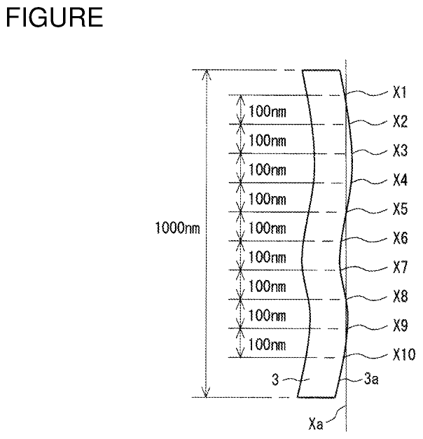

### CROSS-REFERENCE TO RELATED APPLICATIONS

The present application is a continuation-in-part application of International Patent Application No. PCT/JP2022/009373 filed Mar. 4, 2022, which claims priority to Japanese Patent Application No. 2021-040477 filed Mar. 12, 2021. The contents of these applications are incorporated herein by reference in their entirety.

### BACKGROUND OF THE DISCLOSURE

### Technical Field

The present disclosure relates to a composition, a method for manufacturing a semiconductor substrate, a polymer, and a method for manufacturing a polymer.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate (see JP-A-2004-177668).

Various studies have been conducted on materials to be used for such a composition for forming a resist underlayer film (see WO 2011/108365 A).

### SUMMARY

According to an aspect of the present disclosure, a composition includes: a polymer including a repeating unit represented by formula (1); and a solvent. In the formula (1), Ar¹ is a divalent group including an aromatic ring having 10 to 40 ring atoms; and R⁰ is a monovalent group including a heteroaromatic ring which includes a sulfur atom as a ring-forming atom.

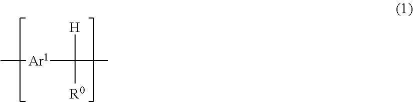

According to another aspect of the present disclosure, a method for manufacturing a semiconductor substrate includes: forming a resist underlayer film directly or indirectly on a substrate by applying the above-described composition; forming a resist pattern directly or indirectly on the resist underlayer film; and performing etching using the resist pattern as a mask.

According to a further aspect of the present disclosure, a polymer includes a repeating unit represented by formula (1).

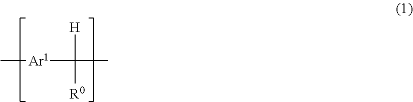

In the formula (1), Ar¹ is a divalent group including an aromatic ring having 10 to 40 ring atoms; and R⁰ is a monovalent group including a heteroaromatic ring which includes a sulfur atom as a ring-forming atom.

According to a further aspect of the present disclosure, a method for producing a polymer includes reacting a first compound including an aromatic ring having 10 to 40 ring atoms with a second compound represented by formula (4-1), (4-2), (4-3) or (4-4).

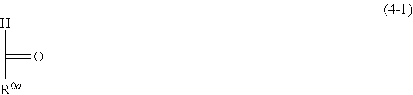

In the formula (4-1), R^{0a} is a monovalent group including a heteroaromatic ring which includes a sulfur atom as a ring-forming atom.

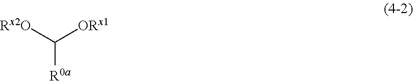

In the formula (4-2), R^{0a} is as defined in the formula (4-1); and R^{x1} and R^{x2} are each independently a monovalent hydrocarbon group having 1 to 10 carbon atoms.

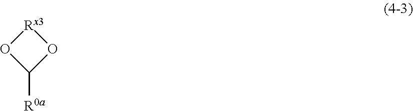

In the formula (4-3), R^{0a} is as defined in the formula (4-1); and R^{x3} is a divalent hydrocarbon group having 1 to 10 carbon atoms.

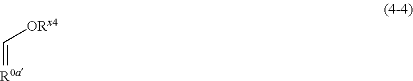

In the formula (4-4), R^{0a′} is a divalent organic group which is obtained by removing one hydrogen atom from the group represented by R^{0a} in the formula (4-1); and R^{x4} is a monovalent hydrocarbon group having 1 to 10 carbon atoms.

### BRIEF DESCRIPTION OF THE DRAWINGS

The FIGURE is a schematic plan view for explaining a method of evaluating bending resistance.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In a multilayer resist process, an organic underlayer film as a resist underlayer film is required to have etching resistance, heat resistance, and bending resistance.

The present invention relates, in one embodiment, to a method for manufacturing a semiconductor substrate, the method including:

applying a composition for forming a resist underlayer film directly or indirectly to a substrate;

forming a resist pattern directly or indirectly on a resist underlayer film formed in applying the composition; and

performing etching using the resist pattern as a mask,

wherein

the composition for forming a resist underlayer film contains:

a polymer having a repeating unit represented by formula (1) (hereinafter, the polymer is also referred to as “polymer [A]”); and

a solvent (hereinafter, the solvent is also referred to as “solvent [B]”),

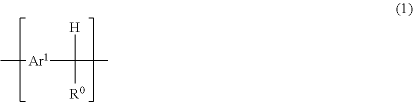

in the formula (1), Ar¹ is a divalent group having an aromatic ring having 10 to 40 ring atoms; and R⁰ is a monovalent group having a heteroaromatic ring containing a sulfur atom as a ring-forming atom.

In the present specification, the term “ring members” refers to the number of atoms constituting the ring. For example, a biphenyl ring has 12 ring members, a naphthalene ring has 10 ring members, and a fluorene ring has 13 ring members.

The present invention relates, in another embodiment, to a composition including:

a polymer having a repeating unit represented by formula (1); and

a solvent,

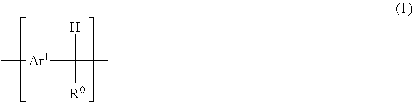

in the formula (1), Ar¹ is a divalent group having an aromatic ring having 10 to 40 ring atoms; and R⁰ is a monovalent group having a heteroaromatic ring containing a sulfur atom as a ring-forming atom.

The present invention relates, in still another embodiment, to a polymer having a repeating unit represented by formula (1),

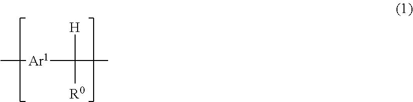

in the formula (1), Ar¹ is a divalent group having an aromatic ring having 10 to 40 ring atoms; and R⁰ is a monovalent group having a heteroaromatic ring containing a sulfur atom as a ring-forming atom.

The present invention relates, in one embodiment, to a method for producing a polymer including:

reacting a compound having an aromatic ring having 10 to 40 ring atoms with a compound represented by formula (4-1), (4-2), (4-3) or (4-4),

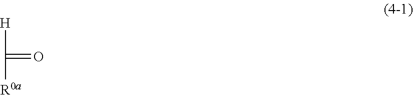

in the formula (4-1), R^{0a} is a monovalent group having a heteroaromatic ring containing a sulfur atom as a ring-forming atom,

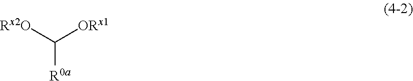

in the formula (4-2), R^{0a} has the same meaning as the formula (4-1); and R^{x1} and R^{x2} are each independently a monovalent hydrocarbon group having 1 to 10 carbon atoms,

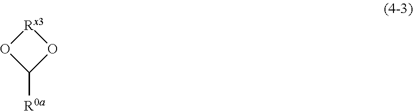

in the formula (4-3), R^{0a} has the same meaning as the formula (4-1); and R^{x3} is a divalent hydrocarbon group having 1 to 10 carbon atoms,

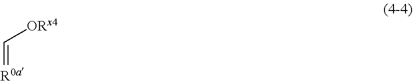

in the formula (4-4), R^{0a′} is a divalent organic group having less one hydrogen atom than R^{0a} in the formula (4-1); and R^{x4} is a monovalent hydrocarbon group having 1 to 10 carbon atoms.

According to the method for manufacturing a semiconductor substrate, since a resist underlayer film superior in etching resistance, heat resistance, and bending resistance is formed, a favorable semiconductor substrate can be obtained. When the composition is used, a film superior in etching resistance, heat resistance, and bending resistance can be formed. The polymer can be suitably used as a component of a composition for forming a resist underlayer film. The method for manufacturing a polymer can efficiently manufacture a polymer suitable as a component of the composition for forming a resist underlayer film. Therefore, they can suitably be used for, for example, producing semiconductor devices expected to be further microfabricated in the future.

Hereinafter, a method for manufacturing a semiconductor substrate, a composition, a polymer, and a method for manufacturing a polymer according to embodiments of the present invention will be described in detail.

### <<Method for Manufacturing Semiconductor Substrate>>

The method for manufacturing a semiconductor substrate includes:

applying a composition for forming a resist underlayer film directly or indirectly to a substrate (hereinafter also referred to as an “applying step”);

forming a resist pattern directly or indirectly on the resist underlayer film formed by the applying step (hereinafter also referred to as a “resist pattern forming step”); and

performing etching using the resist pattern as a mask (hereinafter also referred to as an “etching step”).

According to the method for manufacturing a semiconductor substrate, a resist underlayer film superior in etching resistance, heat resistance, and bending resistance can be formed due to the use of the composition described later as a composition for forming a resist underlayer film in the applying step, so that a semiconductor substrate having a favorable pattern configuration can be manufactured.

The method for manufacturing a semiconductor substrate may further include, as necessary, heating the resist underlayer film formed in the applying step at 300° C. or higher before forming the resist pattern (hereinafter, also referred to as “heating step”).

The method for manufacturing a semiconductor substrate may further include, as necessary, forming a silicon-containing film directly or indirectly on the resist underlayer film formed in the applying step before forming the resist pattern (hereinafter, also referred to as “silicon-containing film forming step”).

Hereinafter, the composition to be used in the method for manufacturing a semiconductor substrate and the respective steps will be described.

### [Composition]

The composition includes a polymer [A] and a solvent [B]. The composition may include an optional component as long as the effect of the composition is not impaired.

Owing to containing the polymer [A] and the solvent [B], the composition can form a film superior in etching resistance, heat resistance, and bending resistance. Accordingly, the composition can be used as a composition for forming a film. Specifically, the composition can be suitably used a composition for forming a resist underlayer film in a multilayer resist process.

Each component contained in the composition will be described below.

### <Polymer [A]>

The polymer [A] has a repeating unit represented by formula (1). The composition can contain one kind or two or more kinds of the polymer [A].

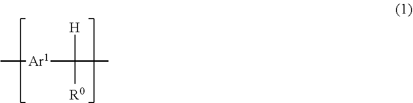

in the formula (1), Ar¹ is a divalent group having an aromatic ring having 10 to 40 ring atoms; and R⁰ is a monovalent group having a heteroaromatic ring containing a sulfur atom as a ring-forming atom.

In the formula (1), examples of the aromatic ring having 10 to 40 ring atoms in Ar¹ include aromatic hydrocarbon rings such as a naphthalene ring, an anthracene ring, a phenalene ring, a phenanthrene ring, a pyrene ring, a fluorene ring, a perylene ring, a coronene ring, an azulene ring, a chrysene ring, a benzopyrene ring, a fluorenylidenebiphenyl ring, and a fluorenylidenebinaphthalene ring; heteroaromatic hydrocarbon rings such as a carbazole ring, a dibenzofuran ring, an acridine ring, and a phenazine ring; and combinations thereof. Examples of the bonding form that provides a combination include a single bond, a double bond, and condensation. The aromatic ring of the Ar¹ is preferably at least one aromatic hydrocarbon ring selected from the group consisting of a naphthalene ring, an anthracene ring, a phenalene ring, a phenanthrene ring, a pyrene ring, a fluorene ring, a perylene ring, and a coronene ring, and more preferably a naphthalene ring or a pyrene ring.

In the formula (1), suitable examples of the divalent group having an aromatic ring having 10 to 40 ring atoms represented by Ar¹ include a group obtained by removing two hydrogen atoms from the aromatic ring having 10 to 40 ring atoms in the Ar¹.

In the formula (1), the heteroaromatic ring in R⁰ is not particularly limited as long as it contains a sulfur atom as a ring-forming atom and the ring structure exhibits aromaticity. Examples of the heteroaromatic ring containing a sulfur atom as a ring-forming atom include a thiophene ring, a thiazole ring, an isothiazole ring, a thiadiazole ring, a thienopyrrole ring, a benzothiophene ring, a benzothiazole ring, a benzisothiazole ring, and combinations thereof. A combination of a heteroaromatic ring and an aromatic hydrocarbon ring (by a single bond, a double bond, condensation, etc.) is also included in the heteroaromatic ring in R⁰. As the aromatic hydrocarbon ring to be combined with the heteroaromatic ring, a benzene ring and the like can be suitably employed as well as the groups recited as the aromatic hydrocarbon ring in the Ar¹.

Suitable examples of the monovalent group having a heteroaromatic ring containing a sulfur atom as a ring-forming atom represented by R⁰ include a group obtained by removing one hydrogen atom from any of the above-described heteroaromatic rings.

The R⁰ is preferably represented by formula (1-1), (1-2) or (1-3).

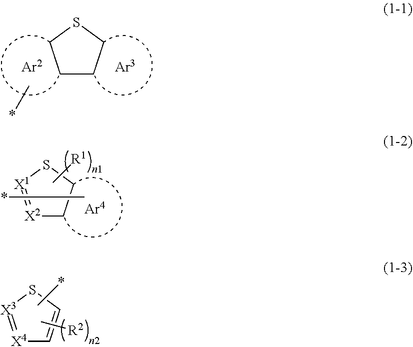

in the formulas (1-1) and (1-2), Ar², Ar³ and Ar⁴ are each independently a substituted or unsubstituted aromatic ring having 6 to 20 ring atoms that forms a fused ring structure together with two adjacent carbon atoms in the formulas (1-1) and (1-2);

in the formula (1-2), X¹ and X² are each independently a carbon atom or a nitrogen atom, provided that at least one of X¹ and X² is a carbon atom; R¹ is an organic group having 1 to 20 carbon atoms; n1 is an integer of 0 to 2; when R¹ is present in a plurality of numbers, the plurality of R¹ are the same or different from each other;

in the formula (1-3), X³ and X⁴ are each independently a carbon atom or a nitrogen atom, provided that at least one of X³ and X⁴ is a carbon atom; R² is an organic group having 1 to 20 carbon atoms; n2 is an integer of 0 to 3; when R² is present in a plurality of numbers, the plurality of R² are the same or different from each other;

in the formulas (1-1), (1-2) and (1-3), * represents a bond to a carbon atom in the formula (1); and in the formula (1-2), the end opposite to * of the bond is bonded to a carbon atom that forms a ring in the formula (1-2).

In the present description, the term “fused ring structure” refers to a structure in which adjacent rings share one side (two adjacent atoms). The term “organic group” refers to a group containing at least one carbon atom.

In the formulas (1-1) and (1-2), suitable examples of the aromatic ring having 6 to 20 ring atoms in Ar², Ar³ and Ar⁴ include aromatic rings corresponding to 10 to 20 ring atoms among the aromatic rings having 10 to 40 ring atoms in Ar¹ of the formula (1), and aromatic rings having 6 to 9 ring atoms such as a benzene ring and a pyridine ring.

Ar², Ar³ and Ar⁴ may have a substituent. Examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, and a nitro group.

Examples of the monovalent organic groups having 1 to 20 represented by R¹ and R² in the formulas (1-2) and (1-3) include a monovalent hydrocarbon group having 1 to 20 carbon atoms, a group containing a divalent heteroatom-containing group between two carbon atoms or at the end of the foregoing hydrocarbon group, a group obtained by substituting some or all of the hydrogen atoms of the foregoing hydrocarbon group with a monovalent heteroatom-containing group, and a combination thereof.

Examples of the monovalent hydrocarbon group having 1 to 20 carbon atoms include monovalent chain hydrocarbon groups having 1 to 20 carbon atoms, monovalent alicyclic hydrocarbon groups having 3 to 20 carbon atoms, monovalent aromatic hydrocarbon groups having 6 to 20 carbon atoms, and combinations thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an i-propyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

In the formula (1-2), n1 is an integer of 0 to 2. n1 is preferably 0 or 1. In the formula (1-3), n2 is an integer of 0 to 3. n2 is preferably an integer of 0 to 2, and more preferably 0 or 1.

The Ar¹ preferably has, as a substituent, at least one group selected from the group consisting of a hydroxy group, a group represented by formula (2-1), and a group represented by formula (2-2). Owing to this, the etching resistance and the heat resistance of a resulting resist underlayer film can be improved.

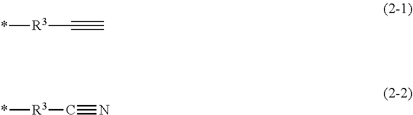

(In the formulas (2-1) and (2-2), R³ is each independently a divalent hydrocarbon group having 1 to 20 carbon atoms or a single bond. * is a bond with a carbon atom in the aromatic ring of the Ar¹.)

Examples of the divalent organic group having 1 to 20 carbon atoms represented by R³ in the formulas (2-1) and (2-2) include a group obtained by removing one hydrogen atom from any of the organic groups having 1 to 20 carbon atoms represented by R¹ and R² in the formulas (1-1) and (1-2). R³ is preferably a divalent hydrocarbon group having 1 to 10 carbon atoms, such as a methanediyl group, an ethanediyl group, or a phenylene group, or a combination of these groups and —O—, and more preferably a methanediyl group or a combination of a methanediyl group and —O—.

When the R⁰ is represented by the formula (1-1), both Ar² and Ar³ are preferably a substituted or unsubstituted benzene ring.

When the R⁰ is represented by the formula (1-2), the R⁰ is preferably represented by any one of formulas (1-2-1) to (1-2-3),

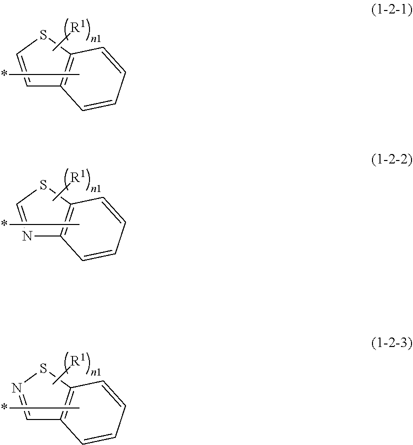

in the formulas (1-2-1) to (1-2-3), R¹ and n1 have the same meanings as the formula (1-2); and in the formulas (1-2-1) to (1-2-3), the end opposite to each * of the bond is bonded to any carbon atom that forms a ring in each of the formulas (1-2-1) to (1-2-3).

When the R⁰ is represented by the formula (1-3), the R⁰ is preferably represented by any one of formulas (1-3-1) to (1-2-3),

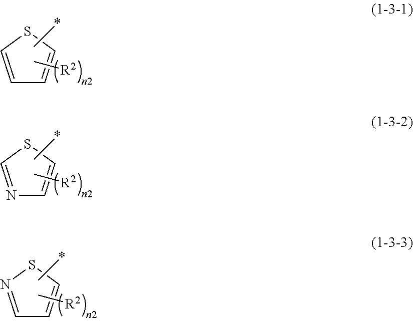

in the formulas (1-3-1) to (1-3-3), R² and n2 have the same meanings as the formula (1-3).

Examples of the repeating unit represented by the formula (1) include repeating units represented by formulas (1-1) to (1-15).

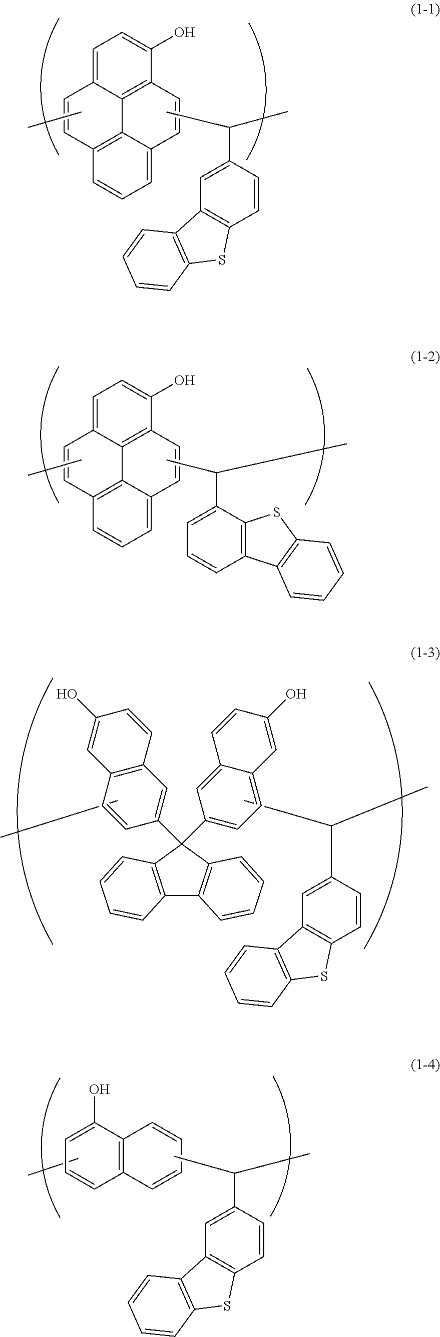

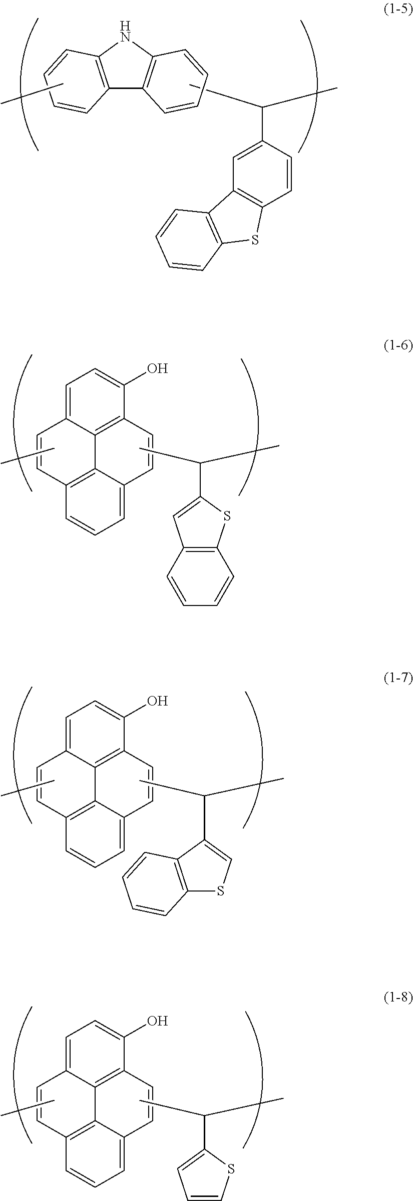

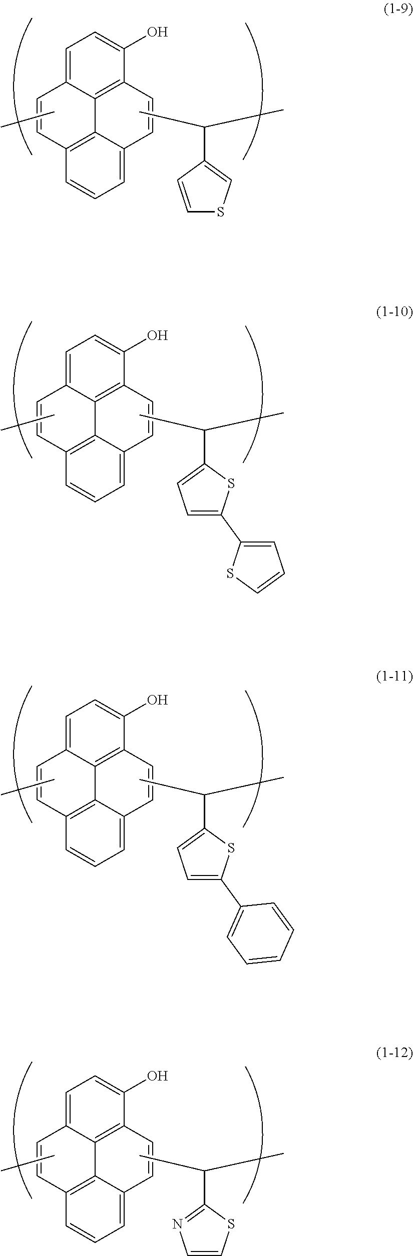

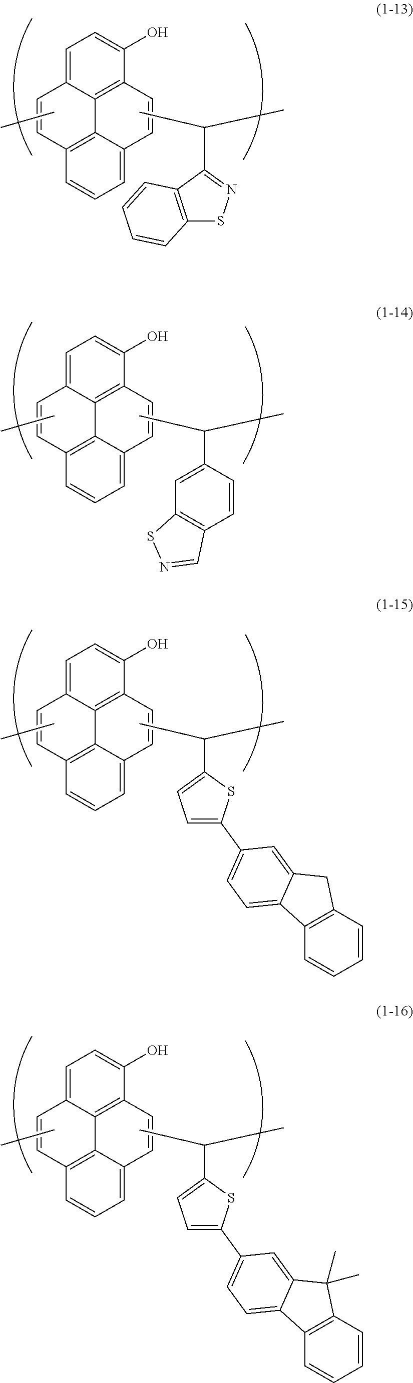

Among them, the repeating units represented by the formulas (1-1) to (1-2) and (1-8) to (1-9) are preferable.

The polymer [A] may further have a repeating unit represented by formula (3).

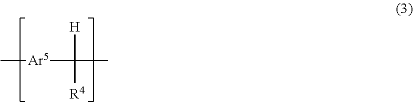

In the formula (3), Ar⁵ is a divalent group having an aromatic ring having 5 to 40 ring atoms; and R⁴ is a hydrogen atom or a monovalent organic group having 1 to 60 carbon atoms, excluding any group corresponding to R⁰ in the formula (1).

As the aromatic ring having 5 to 40 ring atoms in Ar⁵, in addition to aromatic rings having 6 to 9 ring atoms such as a furan ring, a pyrrole ring, a thiophene ring, a phosphole ring, a pyrazole ring, an oxazole ring, an isoxazole ring, a thiazole ring, a benzene ring, or a pyridine ring, the aromatic rings having 10 to 40 ring atoms in Ar¹ of the formula (1) or combinations of two or more thereof can be suitably employed.

Suitable examples of the divalent group having an aromatic ring having 5 to 40 ring atoms represented by Ar⁵ include a group obtained by removing two hydrogen atoms from the aromatic ring having 5 to 40 ring atoms in Ar⁵.

The monovalent organic group having 1 to 60 carbon atoms represented by R⁴ is not particularly limited as long as it is a group other than groups corresponding to R⁰ of the formula (1), and examples thereof include a monovalent hydrocarbon group having 1 to 60 carbon atoms, a group containing a divalent heteroatom-containing group between two carbon atoms of the foregoing hydrocarbon group, a group obtained by substituting some or all of the hydrogen atoms of the foregoing hydrocarbon group with a monovalent heteroatom-containing group, and a combination thereof. As these groups, a group obtained through extension up to 60 carbon atoms of any of the groups recited as examples of the groups constituting the monovalent organic group having 1 to 20 carbon atoms represented by R¹ and R² in the formulas (1-1) and (1-2) can be suitably employed.

Examples of the repeating unit represented by the formula (3) include repeating units represented by formulas (3-1) to (3-5).

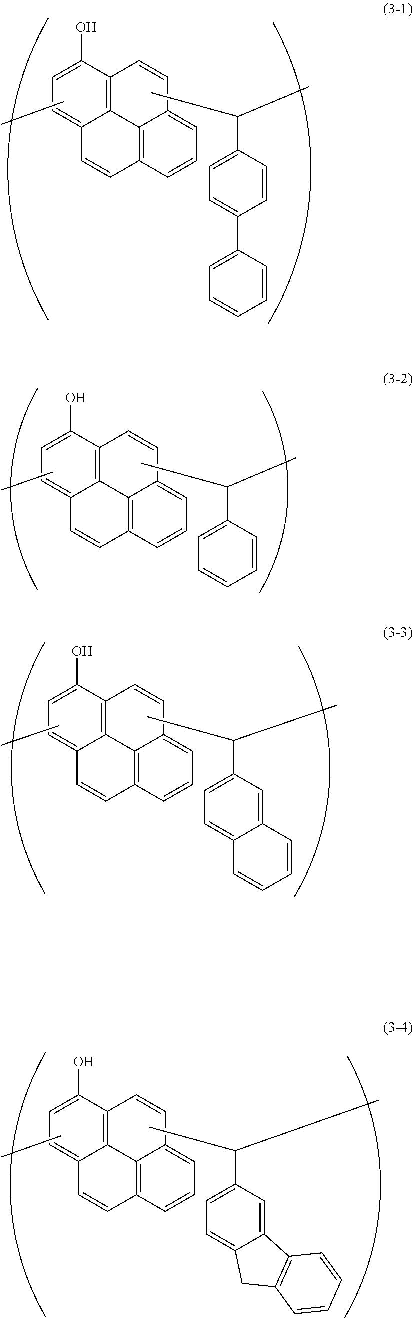

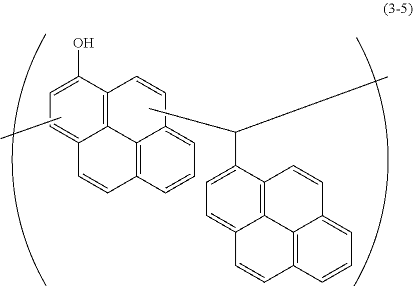

Among them, the repeating units represented by the formulas (3-1) and (3-5) are preferable.

The lower limit of the weight average molecular weight of the polymer [A] is preferably 500, more preferably 800, still more preferably 1200, and particularly preferably 1500. The upper limit of the molecular weight is preferably 10000, more preferably 8000, still more preferably 6000, and particularly preferably 5000. The weight average molecular weight is measured as described in EXAMPLES.

The upper limit of the content ratio of hydrogen atoms to all atoms constituting the polymer [A] is preferably 5.0% by mass, more preferably 4.8% by mass, still more preferably 4.6% by mass, and particularly preferably 4.5% by mass. The lower limit of the content ratio is, for example, 0.1% by mass. By setting the content ratio of hydrogen atoms to all atoms constituting the polymer [A] within the above range, the bending resistance of a resist underlayer film formed of the composition for forming a resist underlayer film can be further improved. The content ratio of hydrogen atoms to all atoms constituting the polymer [A] is a value calculated from the molecular formula of the polymer [A].

The lower limit of content of the polymer [A] in the composition is preferably 2% by mass, more preferably 4% by mass, still more preferably 5% by mass, particularly preferably 6% by mass based on the total mass of the polymer [A] and the solvent [B]. The upper limit of the content is preferably 30% by mass, more preferably 25% by mass, still more preferably 20% by mass, particularly preferably 18% by mass based on the total mass of the polymer [A] and the solvent [B].

<Method for Producing Polymer [A]>

The method for producing a polymer [A] comprises a step of reacting a compound [a] with a compound [b]. In the production method, a novolak-type polymer [A] can be simply and efficiently produced through acid addition condensation of a compound [a] as a precursor to Ar¹ of the formula (1) and a compound [b], which is an aldehyde or an aldehyde derivative, as a precursor to R⁰ of the formula (1).

(Compound [a])

The compound [a] has an aromatic ring having 10 to 40 ring atoms. As the aromatic ring having 10 to 40 ring atoms, the aromatic rings having 10 to 40 ring atoms in Ar¹ of the formula (1) can be suitably employed. The compound [a] preferably has as a substituent any of the groups recited as a substituent in Ar¹.

(Compound [b])

The compound [b] is represented by formula (4-1), (4-2), (4-3), or (4-4) (hereinafter, the compounds represented by the formulas (4-1), (4-2), (4-3) and (4-4) are also referred to as “compound [b1]”, “compound [b2]”, “compound [b3]” and “compound [b4]”, respectively).

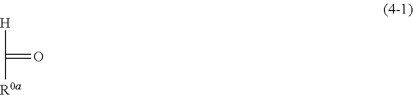

in the formula (4-1), R^{0a} is a monovalent group having a heteroaromatic ring containing a sulfur atom as a ring-forming atom,

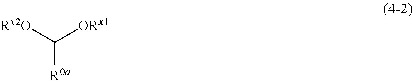

In the formula (4-2), R^{0a} has the same meaning as the formula (4-1); and R^{x1} and R^{x2} are each independently a monovalent hydrocarbon group having 1 to 10 carbon atoms,

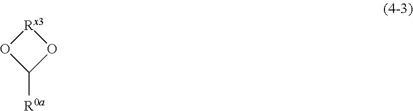

in the formula (4-3), R^{0a} has the same meaning as the formula (4-1); and R^{x3} is a divalent hydrocarbon group having 1 to 10 carbon atoms,

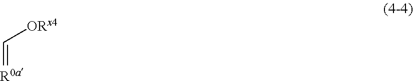

In the formula (4-4), R^{0a′} is a divalent organic group having less one hydrogen atom than R^{0a} in the formula (4-1); and R^{x4} is a monovalent hydrocarbon group having 1 to 10 carbon atoms.

In the compound [b1], as R^{0a} in the formula (4-1), any of the groups recited as R⁰ of the formula (1) can be suitably employed.

In the compound [b2], as the monovalent hydrocarbon group having 1 to 10 carbon atoms represented by R^{x1} and R^{x2}, a group corresponding to 1 to 10 carbon atoms among the monovalent hydrocarbon groups having 1 to 20 carbon atoms represented by R¹ and R² in the formulas (1-2) and (1-3) can be suitably employed.

Suitable examples of the divalent hydrocarbon group having 1 to 10 carbon atoms represented by R^{x3} in the compound [b3] include a group obtained by removing one hydrogen atom from any of the monovalent hydrocarbon groups having 1 to 10 carbon atoms represented by R^{x1} and R^{x2} of the compound [b2].

In the compound [b4], as R^{0a′} of the formula (4-4), a divalent group having less one hydrogen atom than the group recited as R⁰ of the formula (1) can be suitably employed. As the monovalent hydrocarbon group having 1 to 10 carbon atoms represented by R^{x4}, the monovalent hydrocarbon groups having 1 to 10 carbon atoms represented by R^{x1} and R^{x2} of the compound [b2] can be suitably employed.

The addition condensation of the compound [a] and the compound [b] can be performed in accordance with a publicly known method, preferably under an inert gas atmosphere such as a nitrogen gas atmosphere. The lower limit of the reaction temperature of the addition condensation is preferably 50° C., more preferably 70° C., and especially preferably 80° C. The upper limit of the reaction temperature is preferably 200° C., more preferably 160° C., and especially preferably 150° C. The lower limit of the reaction time is preferably 1 hour, more preferably 2 hours, and especially preferably 5 hours. The upper limit of the reaction time is preferably 36 hours, more preferably 24 hours, and especially preferably 20 hours. An acid catalyst is not particularly limited, and publicly known inorganic acids and organic acids can be used. After the addition condensation, the polymer [A] can be obtained through separation, purification, drying, and the like. As the reaction solvent, the solvent [B] described later can be suitably employed.

<Solvent [B]>

The solvent [B] is not particularly limited as long as it can dissolve or disperse the polymer [A] and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], an ester-based solvent or a ketone-based solvent is preferable, a polyhydric alcohol partial ether carboxylate-based solvent or a cyclic ketone-based solvent is more preferable, and propylene glycol monomethyl ether acetate or cyclohexanone is still more preferable.

The lower limit of the content ratio of the solvent [B] in the composition is preferably 50% by mass, more preferably 60% by mass, and still more preferably 70% by mass. The upper limit of the content ratio is preferably 99.9% by mass, more preferably 99% by mass, and still more preferably 95% by mass.

### (Optional Component)

The composition may include an optional component as long as the effect of the composition is not impaired. Examples of the optional component include an acid generator, a crosslinking agent, and a surfactant. The optional component may be used singly or two or more kinds thereof may be used in combination. The content ratio of the optional component in the composition can be appropriately determined according to the type and the like of the optional component.

### [Method for Preparing Composition]

The composition can be prepared by mixing the polymer [A], the solvent [B] and, as necessary, an optional component in a prescribed ratio and preferably filtering the resulting mixture through a membrane filter having a pore size of 0.5 μm or less and the like.

### [Applying Step]

In this step, a composition for forming a resist underlayer film is applied directly or indirectly to a substrate. In this step, the above-mentioned composition is used as a composition for forming a resist underlayer film.

The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

Examples of the case where the composition for forming a resist underlayer film is applied indirectly to the substrate include a case where the composition for forming a resist underlayer film is applied to a silicon-containing film described later formed on the substrate.

### [Heating Step]

In this step, the coating film formed through the applying step is heated. The formation of the resist underlayer film is promoted by heating the coating film. More specifically, volatilization or the like of the solvent [B] is promoted by heating the coating film.

The heating of the coating film may be performed either in the air atmosphere or in a nitrogen atmosphere. The lower limit of the heating temperature is preferably 300° C., more preferably 320° C., and still more preferably 350° C. The upper limit of the heating temperature is preferably 600° C., and more preferably 500° C. The lower limit of the heating time is preferably 15 seconds, and more preferably 30 seconds. The upper limit of the time is preferably 1,200 seconds, and more preferably 600 seconds.

After the applying step, the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and y-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1,500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 30 nm, more preferably 50 nm, and still more preferably 100 nm. The upper limit of the average thickness is preferably 3,000 nm, more preferably 2,000 nm, and still more preferably 500 nm. The average thickness is measured as described in Examples.

### [Silicon-Containing Film Forming Step]

In this step, a silicon-containing film is formed directly or indirectly on the resist underlayer film formed through the applying step or the heating step. Examples of the case where the silicon-containing film is formed indirectly on the resist underlayer film include a case where a surface modification film of the resist underlayer film is formed on the resist underlayer film. The surface modification film of the resist underlayer film is, for example, a film having a contact angle with water different from that of the resist underlayer film.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the resist underlayer film is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and y-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film is a value measured using the spectroscopic ellipsometer in the same manner as for the average thickness of the resist underlayer film.

### [Resist Pattern Forming Step]

In this step, a resist pattern is formed directly or indirectly on the resist underlayer film. Examples of a method for performing this step include a method using a resist composition, a method using nanoimprinting, and a method using a self-assembly composition. Examples of the case of forming a resist pattern indirectly on the resist underlayer film include a case of forming a resist pattern on the silicon-containing film.

Examples of the resist composition include a positive or negative chemically amplified resist composition containing a radiation sensitive acid generator, a positive resist composition containing an alkali-soluble resin and a quinonediazide-based photosensitizer, and a negative resist composition containing an alkali-soluble resin and a crosslinking agent.

Examples of the method of applying the resist composition include a spin coating method. The temperature and time of the prebaking may be appropriately adjusted according to the type or the like of the resist composition to be used.

Then, the formed resist film is subjected to exposure by selective irradiation with radiation. Radiation to be used for the exposure can be appropriately selected according to the type or the like of the radiation-sensitive acid generator to be used in the resist composition, and examples thereof include electromagnetic rays such as visible rays, ultraviolet rays, far-ultraviolet, X-rays, and y-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred.

After the exposure, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include the various organic solvents recited as examples of the solvent [B] in the composition described above.

After the development with a developer, a prescribed resist pattern is formed through washing and drying.

### [Etching Step]

In this step, etching is performed using the resist pattern as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, the resist underlayer film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

<<Composition>>

The composition comprises a polymer [A] and a solvent [B]. As the composition, a composition to be used in the above-described method for manufacturing a semiconductor substrate can be suitably employed.

<<Polymer>>

The polymer is a polymer having a repeating unit represented by the formula (1). As the polymer, the polymer [A] in the composition to be used in the above-described method for manufacturing a semiconductor substrate can be suitably employed.

<<Method for Producing Polymer>>

The method for producing the polymer includes reacting the compound [a] with the compound [b]. As the method for producing the polymer, the method for producing the polymer [A] in the composition to be used in the above-described method for manufacturing a semiconductor substrate can be suitably employed.

### EXAMPLES

Hereinbelow, the present invention will specifically be described on the basis of examples, but is not limited to these examples.

### [Weight-Average Molecular Weight (Mw)]

The Mw of a polymer was measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C.

### [Average Thickness of Film]

The average thickness of a film was determined as a value obtained by measuring the film thickness at arbitrary nine points at intervals of 5 cm including the center of the resist underlayer film formed on a 12-inch silicon wafer using a spectroscopic ellipsometer (“M2000D” available from J. A. WOOLLAM Co.) and calculating the average value of the film thicknesses.

<Synthesis of Polymer [A]>

Polymers having repeating units represented by formulas (A-1) to (A-13) (hereinafter, also referred to as “polymers (A-1) to (A-13)”) and polymers having repeating units represented by formulas (x-1) to (x-4) (hereinafter, also referred to as “polymers (x-1) to (x-4)”) were synthesized by the following procedures.

### [Synthesis Example 1] (Synthesis of Polymer (A-1))

In a nitrogen atmosphere, 20.0 g of 1-hydroxypyrene, 19.5 g of dibenzothiophene-2-carboxaldehyde, and 120.0 g of 1-butanol were charged into a reaction vessel, and the mixture was heated to 80° C. to dissolve. Then, 0.87 g of p-toluenesulfonic acid monohydrate was added thereto, and the mixture was heated to 115° C. and reacted for 15 hours. After completion of the reaction, 200 g of methyl isobutyl ketone and 400 g of water were added thereto, and the organic phase was washed. After the aqueous phase was removed, the organic phase was concentrated using an evaporator, and the residue was charged into 500 g of methanol to reprecipitate. A precipitate was collected on filter paper and dried, affording polymer (A-1). The Mw of the polymer (A-1) was 2,200.

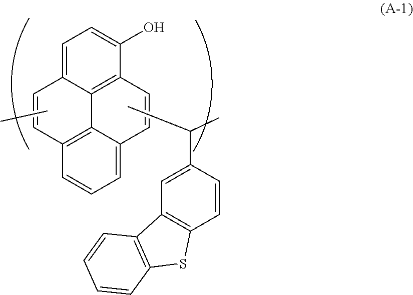

### [Synthesis Example 2] (Synthesis of Polymer (A-2))

Polymer (A-2) was obtained in the same manner as in Synthesis Example 1 except for using 19.5 g of dibenzothiophene-4-carboxaldehyde in place of dibenzothiophene-2-carboxaldehyde. The Mw of the polymer (A-2) was 2,100.

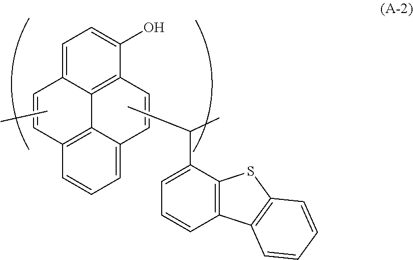

### [Synthesis Example 3] (Synthesis of Polymer (A-3))

Polymer (A-3) was obtained in the same manner as in Synthesis Example 1 except for using 10.0 g of 6,6′-(fluorene-9,9-diyl)bis(naphthalen-2-ol) in place of 1-hydroxypyrene. The Mw of the polymer (A-3) was 5,300.

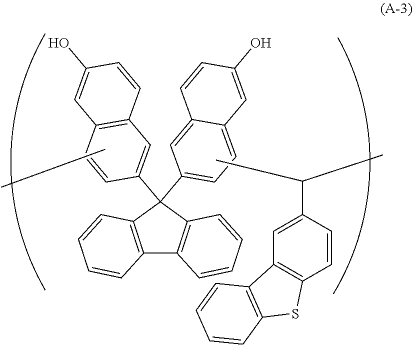

### [Synthesis Example 4] (Synthesis of Polymer (A-4))

Polymer (A-4) was obtained in the same manner as in Synthesis Example 1 except for using 13.2 g of 1-naphthol in place of 1-hydroxypyrene. The Mw of the polymer (A-4) was 2,900.

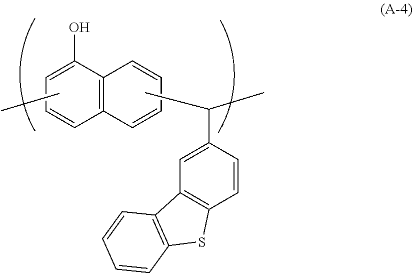

### [Synthesis Example 5] (Synthesis of Polymer (A-5))

Polymer (A-5) was obtained in the same manner as in Synthesis Example 1 except for using 15.2 g of carbazole in place of 1-hydroxypyrene. The Mw of the polymer (A-5) was 3,700.

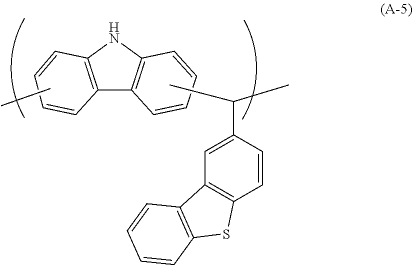

### [Synthesis Example 6] (Synthesis of Polymer (A-6))

Polymer (A-6) was obtained in the same manner as in Synthesis Example 1 except for using 14.9 g of benzo[b]thiophene-2-carboxaldehyde in place of dibenzothiophene-2-carboxaldehyde. The Mw of the polymer (A-6) was 2,500.

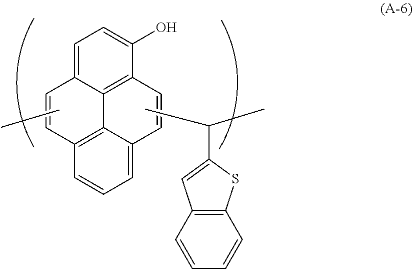

### [Synthesis Example 7] (Synthesis of Polymer (A-7))

Polymer (A-7) was obtained in the same manner as in Synthesis Example 1 except for using 14.9 g of benzo[b]thiophene-3-carboxaldehyde in place of dibenzothiophene-2-carboxaldehyde. The Mw of the polymer (A-7) was 2,300.

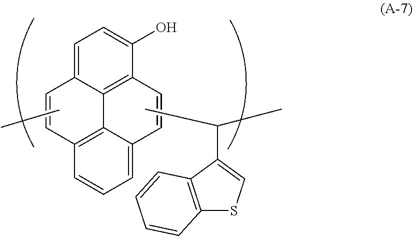

### [Synthesis Example 8] (Synthesis of Polymer (A-8))

Polymer (A-8) was obtained in the same manner as in Synthesis Example 1 except for using 10.2 g of 2-thiophenecarboxaldehyde in place of dibenzothiophene-2-carboxaldehyde. The Mw of the polymer (A-8) was 1,700.

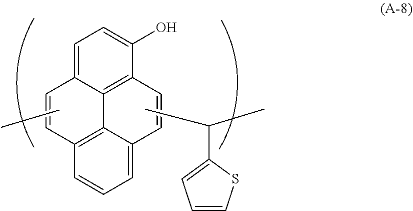

### [Synthesis Example 9] (Synthesis of Polymer (A-9))

Polymer (A-9) was obtained in the same manner as in Synthesis Example 1 except for using 5.1 g of 2-thiophenecarboxaldehyde and 8.3 g of biphenyl-4-carboxaldehyde in place of dibenzothiophene-2-carboxaldehyde. The Mw of the polymer (A-9) was 3,000.

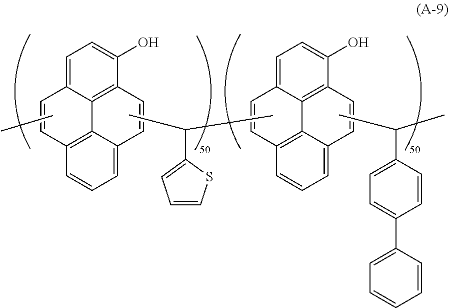

### [Synthesis Example 10] (Synthesis of Polymer (A-10))

Polymer (A-10) was obtained in the same manner as in Synthesis Example 1 except for using 10.2 g of 3-thiophenecarboxaldehyde in place of dibenzothiophene-2-carboxaldehyde. The Mw of the polymer (A-10) was 1,600.

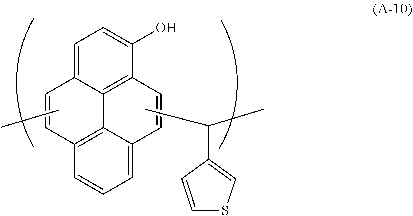

### [Synthesis Example 11] (Synthesis of Polymer (A-11))

Polymer (A-11) was obtained in the same manner as in Synthesis Example 1 except for using 17.7 g of 2,2′-bithiophene-5-carboxaldehyde in place of dibenzothiophene-2-carboxaldehyde. The Mw of the polymer (A-11) was 2,200.

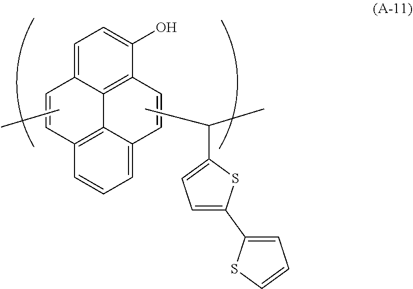

### [Synthesis Example 12] (Synthesis of Polymer (A-12))

Polymer (A-12) was obtained in the same manner as in Synthesis Example 1 except for using 17.1 g of 5-phenylthiophene-2-carboxaldehyde in place of dibenzothiophene-2-carboxaldehyde. The Mw of the polymer (A-12) was 2,400.

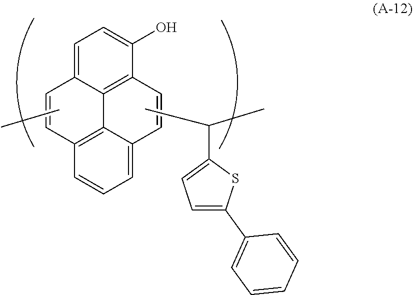

### [Synthesis Example 13] (Synthesis of Polymer (A-13))

Polymer (A-13) was obtained in the same manner as in Synthesis Example 1 except for using 10.3 g of 2-thiazolecarboxaldehyde in place of dibenzothiophene-2-carboxaldehyde. The Mw of the polymer (A-13) was 1,800.

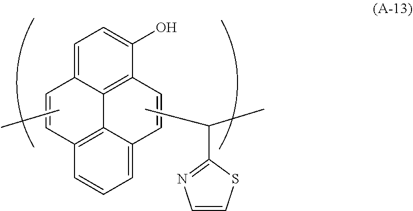

### [Synthesis Example 14] (Synthesis of Polymer (x-1))

In a nitrogen atmosphere, 250.0 g of m-cresol, 125.0 g of 37% by mass formalin, and 2 g of oxalic anhydride were added to a reaction vessel, and the mixture was reacted at 100° C. for 3 hours and at 180° C. for 1 hour, and then unreacted monomers were removed under reduced pressure, affording polymer (x-1). The Mw of the polymer (x-1) obtained was 11,000.

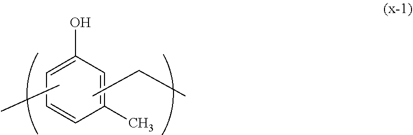

### [Synthesis Example 15] (Synthesis of Polymer (x-2))

In a nitrogen atmosphere, 8.0 g of 9,9-bis(4-hydroxyphenyl)fluorene, 0.8 g of paraformaldehyde, and 21.5 g of methyl isobutyl ketone were charged into a reaction vessel, and the mixture was heated to 80° C. to dissolve. Then, 0.8 g of p-toluenesulfonic acid monohydrate was added thereto, and the mixture was heated to 115° C. and reacted for 15 hours. After completion of the reaction, 100 g of methyl isobutyl ketone and 200 g of water were added thereto, and the organic phase was washed. After the aqueous phase was removed, the organic phase was concentrated using an evaporator, and the residue was charged into 300 g of methanol to reprecipitate. A precipitate was collected on filter paper and dried, affording polymer (x-2). The Mw of the polymer (x-2) was 8,000.

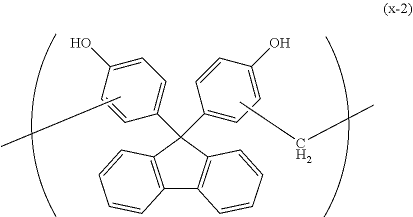

### [Synthesis Example 16] (Synthesis of Polymer (x-3))

In a nitrogen atmosphere, 20.0 g of 1-hydroxypyrene, 18.0 g of dibenzofuran-4-carboxaldehyde, and 120.0 g of 1-butanol were charged into a reaction vessel, and the mixture was heated to 80° C. to dissolve. Then, 0.87 g of p-toluenesulfonic acid monohydrate was added thereto, and the mixture was heated to 115° C. and reacted for 15 hours. After completion of the reaction, 200 g of methyl isobutyl ketone and 400 g of water were added thereto, and the organic phase was washed. After the aqueous phase was removed, the organic phase was concentrated using an evaporator, and the residue was charged into 500 g of methanol to reprecipitate. A precipitate was collected on filter paper and dried, affording polymer (x-3). The Mw of the polymer (x-3) obtained was 2,000.

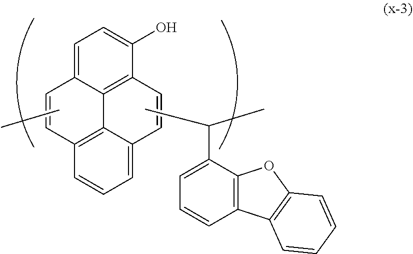

### [Synthesis Example 17] (Synthesis of Polymer (x-4))

Polymer (x-4) was obtained in the same manner as in Synthesis Example 16 except for using 13.9 g of 4-(methylthio)benzaldehyde in place of dibenzofuran-4-carboxaldehyde. The Mw of the polymer (x-4) obtained was 3,100.

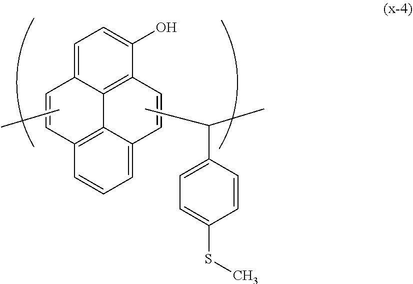

### <Preparation of Composition>

The polymers [A], the solvents [B], the acid generators [C], and the crosslinking agents [D] used for the preparation of compositions are shown below.

### [Polymer [A]]

Examples: Polymers (A-1) to (A-13) synthesized above

Comparative Examples: Polymer (x-1) to (x-4) synthesized above

### [Solvent [B]]

B-1: Propylene glycol monomethyl ether acetate

B-2: Cyclohexanone

### [Acid Generator [C]]

C-1: Bis(4-t-butylphenyl)iodonium nonafluoro-n-butanesulfonate (a compound represented by formula (C-1))

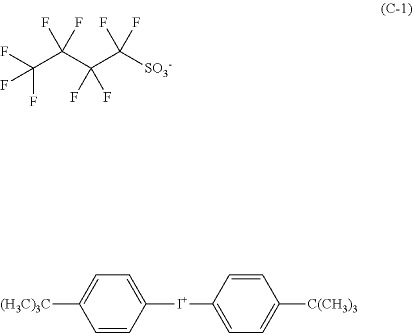

### [Crosslinking Agent [D]]

D-1: A compound represented by formula (D-1)

D-2: A compound represented by formula (D-2)

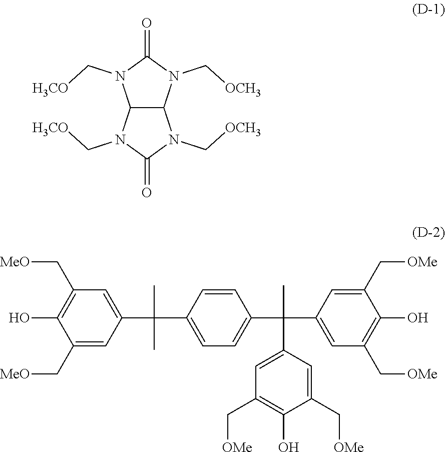 [SMILES: COCN1C(=O)N(COC)C2C1N(COC)C(=O)N2COC ; COCc1cc(C(C)(C)c2ccc(C(C)(c3cc(COC)c(O)c(COC)c3)c3cc(COC)c(O)c(COC)c3)cc2)cc(COC)c1O]

### Example 1

First, 10 parts by mass of (A-1) as the polymer [A] was dissolved in 90 parts by mass of (B-1) as the solvent [B]. The resulting solution was filtered through a polytetrafluoroethylene (PTFE) membrane filter having a pore size of 0.45 μm to prepare composition (J-1).

### Examples 2 to 18 and Comparative Examples 1 to 4

Compositions (J-2) to (J-18) and (CJ-1) to (CJ-4) were prepared in the same manner as in Example 2-1 except that the components of the types and contents shown in the following Table 1 were used. “-” in the columns of “polymer [A]”, “acid generator [C]” and “crosslinking agent [D]” in Table 1 indicates that the corresponding component was not used.

TABLE 1

| | | | | | | | | Acid generator | | Crosslinking | |
|---|---|---|---|---|---|---|---|---|---|---|---|
| | | Polymer [A] | | | | Solvent [B] | | [C] | | agent [D] | |
| | | | Content | | Content | | Content | | Content | | Content |
| | | Type | (parts by | Type | (parts by | | (parts by | | (parts by | | (parts by |
| | Composition | 1 | mass) | 2 | mass) | Type | mass) | Type | mass) | Type | mass) |
| Example 1 | J-1 | A-1 | 10 | — | — | B-1 | 90 | — | — | — | — |
| Example 2 | J-2 | A-2 | 10 | — | — | B-1 | 90 | — | — | — | — |
| Example 3 | J-3 | A-3 | 10 | — | — | B-1 | 90 | — | — | — | — |
| Example 4 | J-4 | A-4 | 10 | — | — | B-1 | 90 | — | — | — | — |
| Example 5 | J-5 | A-5 | 10 | | | B-1 | 90 | — | — | — | — |
| Example 6 | J-6 | A-6 | 10 | — | — | B-1 | 90 | — | — | — | — |
| Example 7 | J-7 | A-7 | 10 | — | — | B-1 | 90 | — | — | — | — |
| Example 8 | J-8 | A-8 | 10 | — | — | B-2 | 90 | — | — | — | — |
| Example 9 | J-9 | A-9 | 10 | — | — | B-1 | 90 | — | — | — | — |
| Example 10 | J-10 | A-10 | 10 | — | — | B-2 | 90 | — | — | — | — |
| Example 11 | J-11 | A-11 | 10 | — | — | B-2 | 90 | — | — | — | — |
| Example 12 | J-12 | A-12 | 10 | — | — | B-2 | 90 | — | — | — | — |
| Example 13 | J-13 | A-13 | 10 | — | — | B-1 | 90 | — | — | — | — |
| Example 14 | J-14 | A-1 | 10 | — | — | B-1 | 85 | C-1 | 5 | — | — |
| Example 15 | J-15 | A-1 | 10 | — | — | B-1 | 85 | — | — | D-1 | 5 |
| Example 16 | J-16 | A-1 | 10 | — | — | B-1 | 80 | C-1 | 5 | D-1 | 5 |
| Example 17 | J-17 | A-1 | 10 | — | — | B-1 | 85 | — | — | D-2 | 5 |
| Example 18 | J-18 | A-1 | 9 | x-1 | 1 | B-1 | 90 | — | — | — | — |
| Comparative | CJ-1 | x-1 | 10 | — | — | B-1 | 80 | C-1 | 5 | D-1 | 5 |
| Example 1 | | | | | | | | | | | |
| Comparative | CJ-2 | x-2 | 10 | — | — | B-1 | 90 | — | — | — | — |
| Example 2 | | | | | | | | | | | |
| Comparative | CJ-3 | x-3 | 10 | — | — | B-1 | 90 | — | — | — | — |
| Example 3 | | | | | | | | | | | |
| Comparative | CJ-4 | x-4 | 10 | — | — | B-1 | 90 | — | — | — | — |
| Example 4 | | | | | | | | | | | |

### <Evaluation>

Using the compositions obtained, etching resistance, heat resistance, and bending resistance were evaluated by the methods described below. The evaluation results are shown in the following Table 2.

### [Etching Resistance]

A composition prepared above was applied to a silicon wafer (substrate) by a spin coating method using a spin coater (“CLEAN TRACK ACT 12” available from Tokyo Electron Limited). Next, the resultant was heated at 350° C. for 60 seconds in the air atmosphere, and then cooled at 23° C. for 60 seconds to form a film having an average thickness of 200 nm, thereby affording a substrate with film, the substrate having the film formed thereon. Using an etching apparatus (“TACTRAS” manufactured by Tokyo Electron Limited), the film on the substrate with film obtained above was processed under the conditions of CF₄/Ar=110/440 sccm, PRESS.=30 MT, HF RF (high-frequency power for plasma generation)=500 W, LF RF (high-frequency power for bias)=3000 W, DCS=−150 V, RDC (gas center flow ratio)=50%, and 30 seconds, and the etching rate (nm/min) was calculated from the average thickness of the film before and after the processing. Next, the ratio with respect to Comparative Example 1 was calculated using the etching rate of Comparative Example 1 as a standard, and this ratio was taken as a measure of etching resistance. The etching resistance was evaluated as “A” (extremely good) when the ratio was 0.65 or less, “B” (good) when the ratio was more than 0.65 and less than 0.69, and “C” (poor) when the ratio was 0.69 or more. “-” in Table 2 indicates that it is an evaluation standard of etching resistance.

### [Heat Resistance]

A composition prepared above was applied to a silicon wafer (substrate) by a spin coating method using a spin coater (“CLEAN TRACK ACT 12” available from Tokyo Electron Limited). Next, the resultant was heated at 200° C. for 60 seconds in the air atmosphere, and then cooled at 23° C. for 60 seconds to form a film having an average thickness of 200 nm, thereby affording a substrate with film, the substrate having the film formed thereon. The film of the substrate with film obtained above was scraped and the resulting powder was collected. The collected powder was placed in a container to be used for measurement with a TG-DTA apparatus (“TG-DTA 2000 SR” manufactured by NETZSCH), and the mass before heating was measured. Next, the powder was heated to 400° C. at a temperature raising rate of 10° C./min in a nitrogen atmosphere using the TG-DTA apparatus, and the mass of the powder at 400° C. was measured. Then, the mass reduction rate (%) was measured from formula, and this mass reduction rate was taken as a measure of heat resistance.

M_{L}={(m1−m2)/m1}×100

Herein, in the above formula, M_{L} is a mass reduction rate (%), m1 is a mass (mg) before heating, and m2 is a mass (mg) at 400° C.

The smaller the mass reduction rate of the powder to be a sample, the smaller the amount of sublimate or decomposition products of the film generated during heating of the film and the better the heat resistance. That is, the smaller the mass reduction rate, the higher the heat resistance. The heat resistance was evaluated as “A” (extremely good) when the mass reduction rate was less than 5%, “B” (good) when the mass reduction rate was 5% or more and less than 10%, and “C” (poor) when the mass reduction rate was 10% or more.

### [Bending Resistance]

The composition prepared as described above was applied to a silicon substrate with a silicon dioxide film formed thereon having an average thickness of 500 nm, by a spin coating method using a spin coater (“CLEAN TRACK ACT 12” available from Tokyo Electron Limited). Next, the resultant was heated at 350° C. for 60 seconds in the air atmosphere, and then cooled at 23° C. for 60 seconds, thereby affording a substrate with film, the substrate having thereon a resist underlayer film having an average thickness of 200 nm. A composition for forming a silicon-containing film (“NFC SOG080” manufactured by JSR Corporation) was applied to the resulting substrate with film by a spin coating method, and then heated at 200° C. for 60 seconds in the air atmosphere, and further heated at 300° C. for 60 seconds, thereby forming a silicon-containing film having an average thickness of 50 nm. A resist composition for ArF (“AR1682J” manufactured by JSR Corporation) was applied to the silicon-containing film by a spin coating method, and heated (fired) at 130° C. for 60 seconds in the air atmosphere, thereby forming a resist film having an average thickness of 200 nm. The resist film was exposed with varying an exposure amount through a 1:1 line-and-space mask pattern with a target size of 100 nm using an ArF excimer laser exposure apparatus (lens numerical aperture: 0.78, exposure wavelength: 193 nm), and then heated (fired) at 130° C. for 60 seconds in the air atmosphere, developed at 25° C. for 1 minute using a 2.38% by mass aqueous tetramethylammonium hydroxide (TMAH) solution, washed with water, and dried, thereby affording a substrate on which a 200 nm-pitch line-and-space resist pattern with a line width of the line pattern of 30 nm to 100 nm was formed.

A silicon-containing film was etched using the resist pattern as a mask and using the aforementioned etching apparatus under the conditions of CF₄=200 sccm, PRESS.=85 mT, HF RF (high-frequency power for plasma generation)=500 W, LF RF (high-frequency power for bias)=0 W, DCS=−150 V, and RDC (gas center flow ratio)=50%, thereby affording a substrate on which a pattern was formed on the silicon-containing film. Subsequently, the resist underlayer film was etched using the silicon-containing film pattern as a mask and using the aforementioned etching apparatus under the conditions of O₂=400 sccm, PRESS.=25 mT, HF RF (high-frequency power for plasma generation)=400 W, LF RF (high-frequency power for bias)=0 W, DCS=0 V, and RDC (gas center flow ratio)=50%, thereby affording a substrate on which a pattern was formed on the resist underlayer film. A silicon dioxide film was etched using the resist underlayer film pattern as a mask and using the aforementioned etching apparatus under the conditions of CF₄=180 sccm, Ar=360 sccm, PRESS.=150 mT, HF RF (high-frequency power for plasma generation)=1,000 W, LF RF (high-frequency power for bias)=1,000 W, DCS=−150 V, RDC (gas center flow ratio)=50%, and 60 seconds, thereby affording a substrate on which a pattern was formed on the silicon dioxide film.

Thereafter, for the substrate on which a pattern was formed on a silicon dioxide film, an image was obtained by enlarging the shape of the resist underlayer film pattern of each line width by a magnification of 250,000 times with a scanning electron microscope (“CG-4000” manufactured by Hitachi High-Technologies Corporation), and then the image was subjected to image processing. Thereby, as shown in the FIGURE, for the lateral side surface 3a of the resist underlayer film pattern 3 (line pattern) having a length of 1,000 nm, a value of 3 sigma, which was obtained by multiplying a standard deviation by 3, the standard deviation having been calculated from the positions Xn (n=1 to 10) in the line width direction measured at 10 points at intervals of 100 nm and the position Xa of the average value of those positions in the line width direction, was defined as LER (line edge roughness). The LER, which indicates the degree of bending of a resist underlayer film pattern, increases as the line width of the resist underlayer film pattern decreases. The bending resistance was evaluated as “A” (good) when the line width of the film pattern having an LER of 5.5 nm was less than 40.0 nm, “B” (slightly good) when the line width was 40.0 nm or more and less than 45.0 nm, and “C” (poor) when the line width was 45.0 nm or more. In the FIGURE, the degree of bending of a film pattern is illustrated with exaggeration than actual one.

TABLE 2

| | | Etching | Heat | Bending |
|---|---|---|---|---|
| | Composition | resistance | resistance | resistance |
| Example 1 | J-1 | A | A | A |
| Example 2 | J-2 | A | A | A |
| Example 3 | J-3 | A | A | B |
| Example 4 | J-4 | B | B | B |
| Example 5 | J-5 | B | B | B |
| Example 6 | J-6 | A | A | A |
| Example 7 | J-7 | A | A | A |
| Example 8 | J-8 | A | A | A |
| Example 9 | J-9 | A | A | B |
| Example 10 | J-10 | A | A | A |
| Example 11 | J-11 | B | B | A |
| Example 12 | J-12 | A | A | B |
| Example 13 | J-13 | B | B | A |
| Example 14 | J-14 | A | A | A |
| Example 15 | J-15 | A | A | A |
| Example 16 | J-16 | A | A | A |
| Example 17 | J-17 | A | A | A |
| Example 18 | J-18 | A | A | A |
| Comparative | CJ-1 | — | C | C |
| Example 1 | | | | |
| Comparative | CJ-2 | C | C | C |
| Example 2 | | | | |
| Comparative | CJ-3 | C | C | B |
| Example 3 | | | | |
| Comparative | CJ-4 | C | C | B |
| Example 4 | | | | |

As can be seen from the results in Table 2, the resist underlayer films formed from the compositions of Examples were superior in etching resistance, heat resistance, and bending resistance to the resist underlayer films formed from the compositions of Comparative Examples.

Using the method for manufacturing a semiconductor substrate of the present disclosure, a favorably-patterned substrate can be obtained. The composition of the present disclosure can form a resist underlayer film superior in etching resistance, heat resistance, and bending resistance. The polymer of the present disclosure can be suitably used as a component of a composition for forming a resist underlayer film. The method for producing a polymer of the present disclosure can efficiently produce a polymer suitable as a component of a composition for forming a resist underlayer film. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A composition comprising:
a polymer comprising a repeating unit represented by formula (1); and
a solvent, 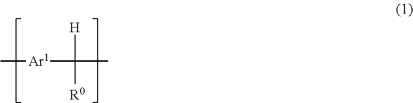
wherein, in the formula (1), Ar¹ is a divalent group comprising an aromatic ring having 10 to 40 ring atoms; and R⁰ is a monovalent group comprising a heteroaromatic ring which comprises a sulfur atom as a ring-forming atom.

2. The composition according to claim 1, wherein R⁰ is a group represented by formula (1-1), (1-2) or (1-3), 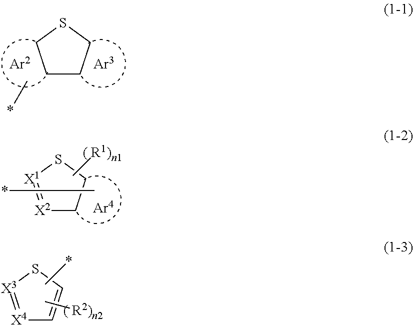
wherein,
in the formulas (1-1) and (1-2), Ar², Ar³ and Ar⁴ are each independently a substituted or unsubstituted aromatic ring having 6 to 20 ring atoms that forms a fused ring structure together with the two adjacent carbon atoms in the formulas (1-1) and (1-2);
in the formula (1-2), X¹ and X² are each independently a carbon atom or a nitrogen atom, provided that at least one of X¹ and X² is a carbon atom; R¹ is an organic group having 1 to 20 carbon atoms; n1 is an integer of 0 to 2; when R¹ is present in a plurality of numbers, the plurality of R¹ are the same or different from each other;
in the formula (1-3), X³ and X⁴ are each independently a carbon atom or a nitrogen atom, provided that at least one of X³ and X⁴ is a carbon atom; R² is an organic group having 1 to 20 carbon atoms; n2 is an integer of 0 to 3; when R² is present in a plurality of numbers, the plurality of R² are the same or different from each other;
in the formulas (1-1), (1-2) and (1-3), * represents a bond to the carbon atom in the formula (1); and in the formula (1-2), the end opposite to * of the bond is bonded to a carbon atom in the fused ring represented by Ar⁴ and the two adjacent carbon atoms in the formula (1-2).

3. The composition according to claim 2, wherein R⁰ is a group represented by formula (1-2) or (1-3).

4. The composition according to claim 1, wherein the aromatic ring included in the divalent group represented by Ar¹ is at least one aromatic hydrocarbon ring selected from the group consisting of a naphthalene ring, an anthracene ring, a phenalene ring, a phenanthrene ring, a pyrene ring, a fluorene ring, a perylene ring, and a coronene ring.

5. The composition according to claim 1, wherein the divalent group represented by Ar¹ comprises at least one group selected from the group consisting of a hydroxy group, a group represented by formula (2-1) and a group represented by formula (2-2), 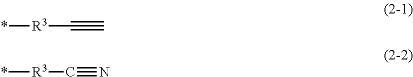
wherein, in the formulas (2-1) and (2-2), R³ is each independently a divalent organic group having 1 to 20 carbon atoms or a single bond; and * is a bond with a carbon atom in the aromatic ring included in the divalent group represented by Ar¹.

6. The composition according to claim 1, wherein the polymer further comprises a repeating unit represented by formula (3), 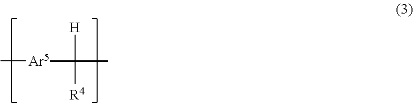
wherein, in the formula (3), Ar⁵ is a divalent group comprising an aromatic ring having 5 to 40 ring atoms; and R⁴ is a hydrogen atom or a monovalent organic group having 1 to 60 carbon atoms, excluding any group corresponding to R⁰ in the formula (1).

7. The composition according to claim 1 that is suitable for forming a resist underlayer film.

8. A method for manufacturing a semiconductor substrate, the method comprising:
forming a resist underlayer film directly or indirectly on a substrate by applying the composition according to claim 1;
forming a resist pattern directly or indirectly on the resist underlayer film; and
performing etching using the resist pattern as a mask.

9. The method according to claim 8, wherein R⁰ is represented by formula (1-1), (1-2) or (1-3), 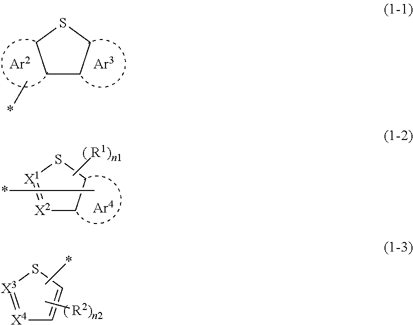
wherein,
in the formulas (1-1) and (1-2), Ar², Ar³ and Ar⁴ are each independently a substituted or unsubstituted aromatic ring having 6 to 20 ring atoms that forms a fused ring structure together with the two adjacent carbon atoms in the formulas (1-1) and (1-2);
in the formula (1-2), X¹ and X² are each independently a carbon atom or a nitrogen atom, provided that at least one of X¹ and X² is a carbon atom; R¹ is an organic group having 1 to 20 carbon atoms; n1 is an integer of 0 to 2; when R¹ is present in a plurality of numbers, the plurality of R¹ are the same or different from each other;
in the formula (1-3), X³ and X⁴ are each independently a carbon atom or a nitrogen atom, provided that at least one of X³ and X⁴ is a carbon atom; R² is an organic group having 1 to 20 carbon atoms; n2 is an integer of 0 to 3; when R² is present in a plurality of numbers, the plurality of R² are the same or different from each other;
in the formulas (1-1), (1-2) and (1-3), * represents a bond to the carbon atom in the formula (1); and in the formula (1-2), the end opposite to * of the bond is bonded to a carbon atom in the fused ring represented by Ar⁴ and the two adjacent carbon atoms in the formula (1-2).

10. The method according to claim 8, further comprising:
forming a silicon-containing film directly or indirectly on the resist underlayer film before forming the resist pattern.

11. A polymer comprising a repeating unit represented by formula (1), 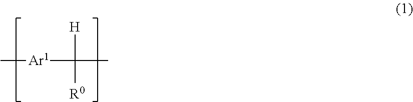
wherein, in the formula (1), Ar¹ is a divalent group comprising an aromatic ring having 10 to 40 ring atoms; and R⁰ is a monovalent group comprising a heteroaromatic ring which comprises a sulfur atom as a ring-forming atom.

12. The polymer according to claim 11, wherein R⁰ is a group represented by formula (1-1), (1-2) or (1-3), 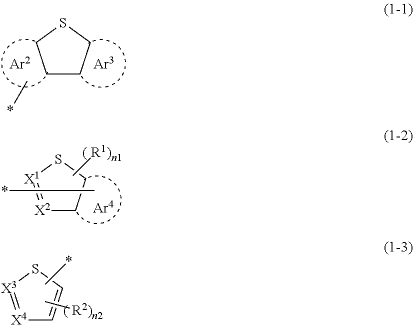
wherein,
in the formulas (1-1) and (1-2), Ar², Ar³ and Ar⁴ are each independently a substituted or unsubstituted aromatic ring having 6 to 20 ring atoms that forms a fused ring structure together with the two adjacent carbon atoms in the formulas (1-1) and (1-2);
in the formula (1-2), X¹ and X² are each independently a carbon atom or a nitrogen atom, provided that at least one of X¹ and X² is a carbon atom; R¹ is an organic group having 1 to 20 carbon atoms; n1 is an integer of 0 to 2; when R¹ is present in a plurality of numbers, the plurality of R¹ are the same or different from each other;
in the formula (1-3), X³ and X⁴ are each independently a carbon atom or a nitrogen atom, provided that at least one of X³ and X⁴ is a carbon atom; R² is an organic group having 1 to 20 carbon atoms; n2 is an integer of 0 to 3; when R² is present in a plurality of numbers, the plurality of R² are the same or different from each other;
in the formulas (1-1), (1-2) and (1-3), * represents a bond to the carbon atom in the formula (1); and in the formula (1-2), the end opposite to * of the bond is bonded to a carbon atom in the fused ring represented by Ar⁴ and the two adjacent carbon atoms in the formula (1-2).

13. The method according to claim 12, wherein R⁰ is a group represented by formula (1-2) or (1-3).

14. The polymer according to claim 11, wherein the aromatic ring included in the divalent group represented by Ar¹ is a divalent group comprising at least one aromatic hydrocarbon ring selected from the group consisting of a naphthalene ring, an anthracene ring, a phenalene ring, a phenanthrene ring, a pyrene ring, a fluorene ring, a perylene ring, and a coronene ring.

15. The polymer according to claim 11, wherein the divalent group represented by Ar¹ comprises at least one group selected from the group consisting of a hydroxy group, a group represented by formula (2-1) and a group represented by formula (2-2), 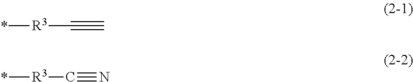
wherein, in the formulas (2-1) and (2-2), R³ is each independently a divalent organic group having 1 to 20 carbon atoms or a single bond; and * is a bond with a carbon atom in the aromatic ring included in the divalent group represented by Ar¹.

16. The polymer according to claim 11, wherein the polymer further comprises a repeating unit represented by formula (3), 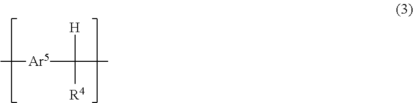
wherein, in the formula (3), Ar⁵ is a divalent group comprising an aromatic ring having 5 to 40 ring atoms; and R⁴ is a hydrogen atom or a monovalent organic group having 1 to 60 carbon atoms, excluding any group corresponding to R⁰ in the formula (1).

17. A method for producing a polymer comprising:
reacting a first compound comprising an aromatic ring having 10 to 40 ring atoms with a second compound represented by formula (4-1), (4-2), (4-3) or (4-4), 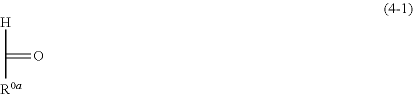
wherein, in the formula (4-1), R^{0a} is a monovalent group comprising a heteroaromatic ring which comprises a sulfur atom as a ring-forming atom, 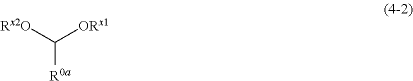
wherein, in the formula (4-2), R^{0a} is as defined in the formula (4-1); and R^{x1} and R^{x2} are each independently a monovalent hydrocarbon group having 1 to 10 carbon atoms, 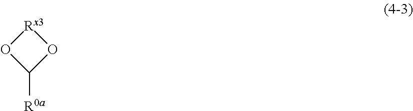
wherein, in the formula (4-3), R^{0a} is as defined in the formula (4-1); and R^{x}3 is a divalent hydrocarbon group having 1 to 10 carbon atoms, 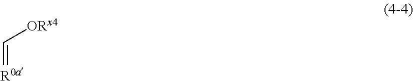
wherein, in the formula (4-4), R^{0a′} is a divalent organic group which is obtained by removing one hydrogen atom from the group represented by R^{0a} in the formula (4-1); and R^{x4} is a monovalent hydrocarbon group having 1 to 10 carbon atoms.

18. The method according to claim 17, wherein R^{0a} is a group represented by formula (1-1), (1-2) or (1-3), 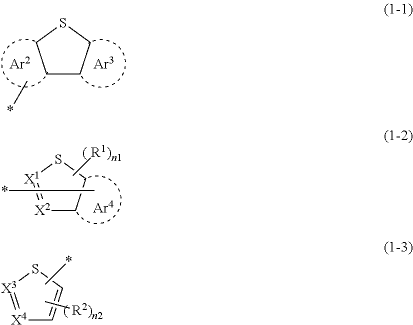
wherein,
in the formulas (1-1) and (1-2), Ar², Ar³ and Ar⁴ are each independently a substituted or unsubstituted aromatic ring having 6 to 20 ring atoms that forms a fused ring structure together with the two adjacent carbon atoms in the formulas (1-1) and (1-2);
in the formula (1-2), X¹ and X² are each independently a carbon atom or a nitrogen atom, provided that at least one of X¹ and X² is a carbon atom; R¹ is an organic group having 1 to 20 carbon atoms; n1 is an integer of 0 to 2; when R¹ is present in a plurality of numbers, the plurality of R¹ are the same or different from each other;
in the formula (1-3), X³ and X⁴ are each independently a carbon atom or a nitrogen atom, provided that at least one of X³ and X⁴ is a carbon atom; R² is an organic group having 1 to 20 carbon atoms; n2 is an integer of 0 to 3; when R² is present in a plurality of numbers, the plurality of R² are the same or different from each other;
in the formulas (1-1), (1-2) and (1-3), * represents a bond to the carbon atom in the formula (1); and in the formula (1-2), the end opposite to * of the bond is bonded to a carbon atom in the fused ring represented by Ar⁴ and the two adjacent carbon atoms in the formula (1-2).

19. The method according to claim 17, wherein the aromatic ring having 10 to 40 ring atoms included in the first compound is at least one aromatic hydrocarbon ring selected from the group consisting of a naphthalene ring, an anthracene ring, a phenalene ring, a phenanthrene ring, a pyrene ring, a fluorene ring, a perylene ring, and a coronene ring.
